(19) United States
(12) Patent Application Publication
(10) Pub. No.: US 2015/0364590 A1
(43) Pub. Date: Dec. 17, 2015

(54) SEMICONDUCTOR DEVICE AND METHOD OF MANUFACTURING THE SAME

(71) Applicant: KABUSHIKI KAISHA TOSHIBA, Tokyo (JP)

(72) Inventors: Tetsuya Ohno, Nomi Ishikawa (JP); Akira Yoshioka, Nomi Ishikawa (JP)

(21) Appl. No.: 14/643,272

(22) Filed: Mar. 10, 2015

(30) Foreign Application Priority Data
Jun. 11, 2014 (JP) 2014-120578

(51) Int. Cl. H01L 29/778; H01L 29/66

(52) U.S. Cl. CPC H01L 29/7788; H01L 29/66431

(57) ABSTRACT

In one embodiment, a semiconductor device includes a first semiconductor layer of a first conductivity type or an intrinsic type, and a second semiconductor layer of a second conductivity type provided on the first semiconductor layer. The device further includes a third semiconductor layer of the first conductivity type provided on the second semiconductor layer, and a fourth semiconductor layer in contact with the first, second and third semiconductor layers. The device further includes a fifth semiconductor layer provided on a semi-polar face of the fourth semiconductor layer, and a control electrode provided on the fifth semiconductor layer through an insulating layer.

### CROSS REFERENCE TO RELATED APPLICATION

This application is based upon and claims the benefit of priority from the prior Japanese Patent Application No. 2014-120578, filed on Jun. 11, 2014, the entire contents of which are incorporated herein by reference.

### FIELD

Embodiments described herein relate to a semiconductor device and a method of manufacturing the same.

### BACKGROUND

Since a field effect transistor using a nitride semiconductor material has a large band gap and a high electric field strength, the transistor is expected to be applied to a high-frequency device or a power control device as a next generation power semiconductor device that can operate at a high-power, high-voltage and high-temperature. For example, it is known that a two-dimensional electron gas (2DEG) layer is spontaneously generated on a heterointerface between a gallium nitride (GaN) layer and an aluminum gallium nitride (AlGaN) layer due to a polarization effect. At the heterointerface, these layers are joined. An example of the transistor using this 2DEG layer as a channel is a high electron mobility transistor (HEMT).

A vertical HEMT as an example of the HEMT has a structure optimum for a switching device or the like that is required to operate at a low on resistance, high-voltage and high current. In addition, an example of a cell structure of the vertical HEMT includes a structure in which a source electrode is disposed on one side of a gate electrode. The vertical HEMT having such a structure offer an advantage that the size of the semiconductor device can be reduced by reducing a cell pitch. However, in a case where the AlGaN layer is stacked on the GaN layer, the vertical HEMT exerts a normally-on operation in which it is in an on state when a bias voltage is not applied, since the 2DEG layer is generated on the heterointerface between the GaN layer and the AlGaN layer. It is desired that the HEMT exerts, from the viewpoint of safety, a normally-off operation in which it is in an off state when the bias voltage is not applied, and has a low on resistance and a high electron mobility.

### BRIEF DESCRIPTION OF THE DRAWINGS

FIG. 1 is a cross sectional view showing a structure of a semiconductor device of a first embodiment;

FIGS. 2A and 2B are diagrams for illustrating crystal planes of an electron transport layer of the first embodiment;

FIGS. 3A to 5B are cross sectional views showing a method of manufacturing the semiconductor device of the first embodiment;

FIG. 6 is a cross sectional view showing a structure of a semiconductor device of a second embodiment;

FIGS. 7A to 7C are cross sectional views showing a method of manufacturing the semiconductor device of the second embodiment;

FIG. 8 is a cross sectional view showing a structure of a semiconductor device of a third embodiment;

FIGS. 9A and 9B are cross sectional views showing a method of manufacturing the semiconductor device of the third embodiment;

FIGS. 10A to 10C are cross sectional views and a plan view showing a structure of a semiconductor device of a fourth embodiment;

FIGS. 11A to 14C are cross sectional views and plan views showing a method of manufacturing the semiconductor device of the fourth embodiment;

FIG. 15 is a cross sectional view showing a structure of a semiconductor device of a fifth embodiment; and

FIGS. 16A to 20C are cross sectional views and plan views showing a method of manufacturing the semiconductor device of the fifth embodiment.

### DETAILED DESCRIPTION

Embodiments will now be explained with reference to the accompanying drawings.

In one embodiment, a semiconductor device includes a first semiconductor layer of a first conductivity type or an intrinsic type, and a second semiconductor layer of a second conductivity type provided on the first semiconductor layer. The device further includes a third semiconductor layer of the first conductivity type provided on the second semiconductor layer, and a fourth semiconductor layer in contact with the first, second and third semiconductor layers. The device further includes a fifth semiconductor layer provided on a semi-polar face of the fourth semiconductor layer, and a control electrode provided on the fifth semiconductor layer through an insulating layer.

### First Embodiment

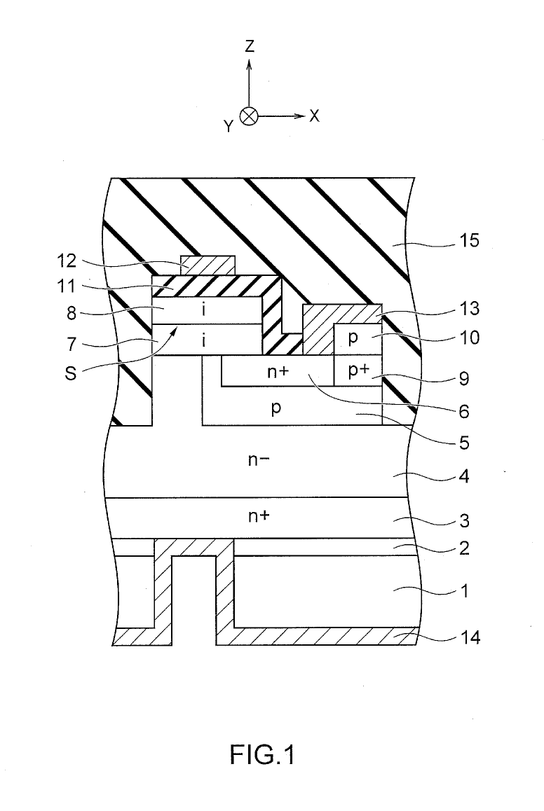

FIG. 1 is a cross sectional view showing a structure of a semiconductor device of a first embodiment. The semiconductor device in FIG. 1 includes a vertical HEMT.

The semiconductor device in FIG. 1 includes a substrate 1, a buffer layer 2, a first n type contact layer 3, a drift layer 4 as an example of a first semiconductor layer, a p type semiconductor layer 5 as an example of a second semiconductor layer, a second n type contact layer 6 as an example of a third semiconductor layer, an electron transport layer 7 as an example of a fourth semiconductor layer, an electron supply layer 8 as an example of a fifth semiconductor layer, a p type contact layer 9, and a p type source layer 10.

Furthermore, the semiconductor device in FIG. 1 includes a gate insulator 11 as an example of an insulating layer, a gate electrode 12 as an example of a control electrode, a source electrode 13 as an example of a first electrode, a drain electrode 14 as an example of a second electrode, and an interlayer dielectric 15.

Reference characters n, p, and i shown in FIG. 1 denote semiconductor layers of an n type, p type, and i type (intrinsic type), respectively. The n type and the p type are examples of first and second conductivity types. The semiconductor layer of an i type means a semiconductor layer in which an n type impurity and a p type impurity are not intentionally contained. The semiconductor layer of the i type is also called an undoped semiconductor layer.

An example of the substrate 1 is a semiconductor substrate such as a silicon substrate. FIG. 1 shows an X direction and a Y direction that are parallel to the substrate 1 and orthogonal to each other, and a Z direction that is orthogonal to the substrate 1. In the present specification, a +Z direction is treated as an upward direction, and a −Z direction is treated as a downward direction. For example, the positional relationship between the substrate 1 and the interlayer dielectric 15 is expressed that the substrate 1 is positioned below the interlayer dielectric 15.

The buffer layer 2 is formed on the substrate 1. An example of the buffer layer 2 is a stack film that includes an AlN (aluminum nitride) layer, an AlGaN layer, a GaN layer, and the like. Examples of the buffer layer 2 include one in which carbon atoms are doped.

The first n type contact layer 3 is formed on the buffer layer 2, and is in contact with the drain electrode 14. An example of the first n type contact layer 3 is an n+ type GaN layer with an n type impurity doped at a relatively high concentration. An example of this n type impurity is a silicon (Si) atom. The first n type contact layer 3 is provided for reducing a contact resistance with the drain electrode 14.

The drift layer 4 is formed on the first n type contact layer 3. An example of the drift layer 4 is an n− type GaN layer with an n type impurity doped at a concentration lower than that of the first n type contact layer 3, and may be an i type GaN layer. The drift layer 4 is in contact with the lower portion and the side portion of the p type semiconductor layer 5.

The p type semiconductor layer 5 is formed on the drift layer 4. An example of the p type semiconductor layer 5 is a p type GaN layer with a p type impurity doped. An example of this p type impurity is a magnesium (Mg) atom. The p type semiconductor layer 5 is in contact with the lower portion and the side portion of the second n type contact layer 6. The p type semiconductor layer 5 in the vicinity of the electron transport layer 7 is sandwiched between the drift layer 4 and the second n type contact layer 6, and functions as a channel of the HEMT.

The second n type contact layer 6 is formed on the p type semiconductor layer 5, and is in contact with the source electrode 13. An example of the second n type contact layer 6 is an n+ type GaN layer. In order to reduce a contact resistance with the source electrode 13, the concentration of the n type impurity of the second n type contact layer 6 is set higher than the concentration of the n type impurity of the drift layer 4.

The electron transport layer 7 is formed on the drift layer 4, the p type semiconductor layer 5, and the second n type contact layer 6. The drift layer 4, the p type semiconductor layer 5, and the second n type contact layer 6 of the present embodiment are in contact with the lower portion of the electron transport layer 7. An example of the electron transport layer 7 is an i type GaN layer. An upper face S of the electron transport layer 7 of the present embodiment is a semi-polar face. The semi-polar face will be described in detail hereafter.

The electron supply layer 8 is formed on the upper face S of the electron transport layer 7. Therefore, the electron supply layer 8 is in contact with the semi-polar face of the electron transport layer 7. An example of the electron supply layer 8 is an i type AlGaN layer.

The p type contact layer 9 is formed on the p type semiconductor layer 5, and is in contact with the side portion of the second n type contact layer 6. An example of the p type contact layer 9 is a p+ type GaN layer with a p type impurity doped at a concentration higher than that of the p type semiconductor layer 5. The p type contact layer 9 is provided for drawing out, by the avalanche breakdown at the time of applying a high voltage, positive holes accumulated in the buffer layer 2, the drift layer 4, and the p type semiconductor layer 5, and the like into the source electrode 13. The p type contact layer 9 is a layer for reducing a potential difference between the source electrode 13 and the p type semiconductor layer 5 by being connected to the source electrode 13 via the p type source layer 10 so as to fix the electric potential of the p type semiconductor layer 5. According to the present embodiment, it is possible to prevent a kink phenomenon in which the increase of positive holes accumulated in the semiconductor device due to the avalanche breakdown at the time of applying a high voltage causes a drain current to sharply increase.

The p type source layer 10 is formed on the p type contact layer 9, and is a layer for being in contact with the source electrode 13. The p type source layer 10 is provided for reducing a contact resistance with the source electrode 13.

The gate insulator 11 is formed on the electron supply layer 8. The upper portion and the side portion of the electron supply layer 8, the side portion of the electron transport layer 7, and the upper portion of the second n type contact layer 6 are covered with the gate insulator 11 of the present embodiment. An example of the gate insulator 11 is a silicon dioxide film.

The gate electrode 12 is formed on the electron supply layer 8 via the gate insulator 11. An example of the gate electrode 12 is a metal layer. An example of this metal layer is a stack film that includes at least any one of a platinum (Pt) layer, a nickel (Ni) layer, and a gold (Au) layer. The gate electrode 12 has a shape extending in the Y direction.

The source electrode 13 is formed on the second n type contact layer 6 and the p type source layer 10, and is in contact with the upper portion of the second n type contact layer 6, and the upper portion and the side portion of the p type source layer 10. The source electrode 13 has a shape extending in the Y direction.

The drain electrode 14 is formed below the first n type contact layer 3, and is in contact with the lower portion of the first n type contact layer 3. The drain electrode 14 has a shape extending in the Y direction. The drain electrode 14 of the present embodiment is further in contact with the lower portion and the side portions of the substrate 1, and the side portions of the buffer layer 2.

The interlayer dielectric 15 is formed such that the HEMT is covered therewith on the substrate 1. An example of the interlayer dielectric 15 is a silicon dioxide film.

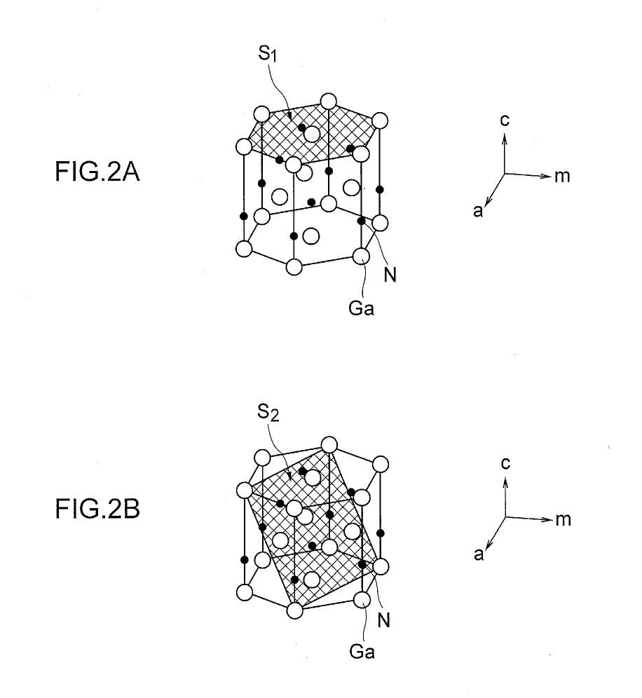

FIGS. 2A and 2B are diagrams for illustrating crystal planes of the electron transport layer 7 of the first embodiment.

The electron transport layer 7 of the present embodiment is a GaN layer. FIGS. 2A and 2B show the crystal structure of the GaN layer, and the directions of a c-axis, an m-axis, and an a-axis of the GaN layer. A GaN crystal has a wurtzite crystal structure, the plane orientation of the crystal plane of the GaN crystal is represented with a four-index scheme (hexagonal indices).

FIG. 2A shows a polar face S₁ of the GaN crystal. The polar face S₁ is a c-plane, and the Miller index thereof is (0001). The c-plane is a plane on which a maximum polarity appears. In a case where an AlGaN crystal is formed on the polar face S₁ of the GaN crystal, a piezo electric field is generated in a c-axis direction of the polar face S₁.

FIG. 2B shows a semi-polar face S₂ of the GaN crystal. The semi-polar face S₂ is a crystal plane that is nonparallel and nonorthogonal to the polar face S₁. Examples of the Miller index of the semi-polar face S₂ shown in FIG. 2B include (11-22), (10-1-1), (10-1-3), and the like. In a case where an AlGaN crystal is formed on the semi-polar face S₂ of the GaN crystal, the semi-polar face S₂ has a crystal axis along which a piezo electric field is smaller than the piezo electric field existing along the c-axis direction on the polar face S₁.

On a heterointerface between the GaN crystal and the AlGaN crystal, an internal electric field is generated by a synergistic effect between piezo polarization and spontaneous polarization due to lattice distortion in a heterojunction of a GaN and an AlGaN, and a high-density 2DEG layer is formed, which causes the HEMT to exert a normally-on operation. In the case where an AlGaN crystal is formed on the semi-polar face S₂ of the GaN crystal, as compared with the case where an AlGaN crystal is formed on the polar face S₁ of the GaN crystal, the polarity is reduced to such an extent that the HEMT exerts a normally-off operation, and the density of 2DEG is reduced.

Next, referring to FIG. 1 again, the semiconductor device of the first embodiment will be described.

In a case where the upper face S of the electron transport layer 7 is a polar face and the electron supply layer 8 is formed on this polar face, the vertical HEMT in FIG. 1 is to exert a normally-on operation by 2DEG generated on a heterointerface between the electron transport layer 7 and the electron supply layer 8.

However, since the upper face S of the electron transport layer 7 of the present embodiment is a semi-polar face, the electron supply layer 8 is stacked on the semi-polar face of the electron transport layer 7. Therefore, in the present embodiment, as compared with the case where the electron supply layer 8 is formed on the polar face of the electron transport layer 7, the density of the 2DEG is reduced to such an extent that a normally-off operation is substantially enabled. Therefore, according to the present embodiment, suppressing the amount of the 2DEG generation on the semi-polar face causes the HEMT in FIG. 1 to exert a normally-off operation, which enables reducing an on resistance at the time of applying a bias voltage and enhancing the electron mobility.

In addition, the HEMT of the present embodiment has a structure in which the source electrode 13 is disposed only on one side of the gate electrode 12. In addition, the p type semiconductor layer 5 of the present embodiment pinches off a channel, having a function as a barrier layer. In a case where a structure that the electron transport layer 7 and the electron supply layer 8 are not stacked on the p type semiconductor layer 5 is adopted, when the surface of the p type semiconductor layer 5 is damaged by an etching process or the like, the p type semiconductor layer 5 is made into an n type one or is made highly resistive. In such a structure, a channel resistance at the time of applying a bias voltage increases and the electron mobility is reduced. In contrast, according to the present embodiment, by providing the electron supply layer 8 on the upper face S of the electron transport layer 7, it is possible to pinch off the channel to enhance the electron mobility even if a bias voltage is zero. The cell structure of the present embodiment can have a shape such as a polygon, circle, and irregular shape.

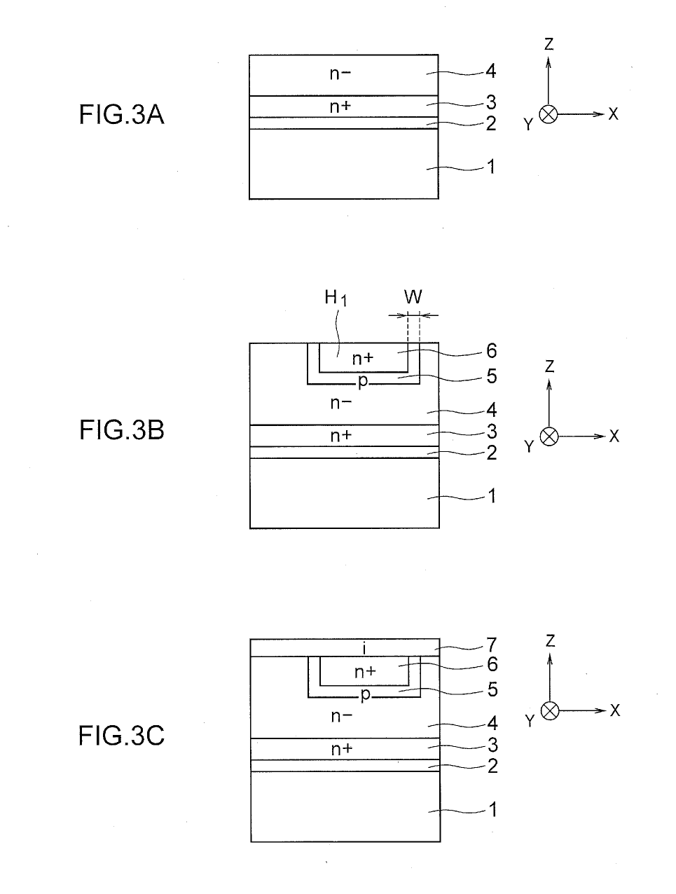

FIGS. 3A to 5B are cross sectional views showing a method of manufacturing the semiconductor device of the first embodiment.

First, as shown in FIG. 3A, the buffer layer 2, the first n type contact layer 3, and the drift layer 4 are sequentially formed on the substrate 1. The upper face of the drift layer 4 is, for example, a (0001) plane.

Next, as shown in FIG. 3B, by means of lithography and RIE (Reactive Ion Etching), an opening H₁ is formed in the drift layer 4. Next, the p type semiconductor layer 5 is formed on the side portions and the lower portion of the opening H₁. Next, the second n type contact layer 6 is formed in the opening H₁ through the p type semiconductor layer 5. Reference character W denotes the width of the uppermost portions of the p type semiconductor layer 5 in the X direction. The width W is set to such a width that electrons (2DEG) in the channel are depleted, and for example, is set to 100 nm or less. Alternatively, an n type impurity may be ion implanted in the p type semiconductor layer 5 to form the second n type contact layer 6.

Next, as shown in FIG. 3C, the electron transport layer 7 is grown on the drift layer 4, the p type semiconductor layer 5, and the second n type contact layer 6. The thickness of the electron transport layer 7 in FIG. 3C is set to such a thickness that electron mobility or pinch-off are not degraded, and for example, distances between the uppermost faces of the p type semiconductor layer 5 and the electron supply layer 8 to be described hereafter are 100 nm or less. The upper face of the electron transport layer 7 in FIG. 3C is a polar face.

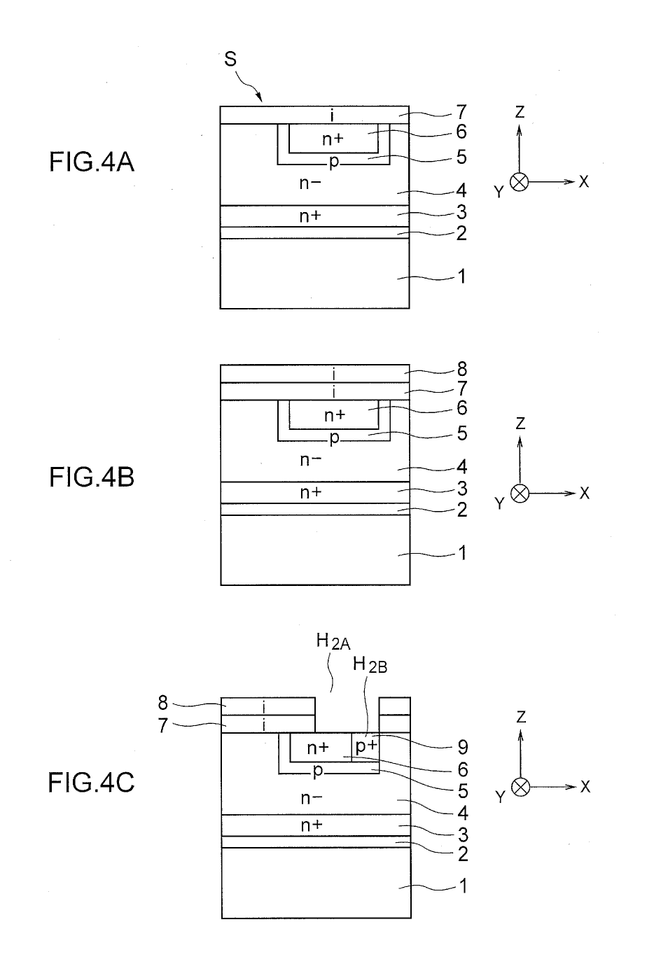

Next, a resist is applied on the electron transport layer 7 in FIG. 3C, and a resist mask having an opening in an formation planned area of the HEMT is formed on the electron transport layer 7 by means of lithography. Next, a step is formed in the electron transport layer 7 by means of etching or the like using this resist mask. Next, a wafer is subjected to heat treatment in an atmosphere containing NH₃ (ammonia) gas. Consequently, the upper face S of the electron transport layer 7 is made a semi-polar face (FIG. 4A).

Next, as shown in FIG. 4B, the electron supply layer 8 is formed on the upper face S of the electron transport layer 7. An example of the thickness of the electron supply layer 8 is 25 nm.

Subsequently, a method and a process of forming an ohmic contact will be described.

Next, as shown in FIG. 4C, a resist (not shown) is applied on the electron supply layer 8, and a first opening H_{2A} that penetrates the electron supply layer 8 and the electron transport layer 7 is formed by means of lithography and RIE. Subsequently, the resist mask is removed through a liftoff process.

Next, as shown in FIG. 4C, a resist (not shown) is applied on the whole wafer surface, by means of lithography and RIE, a second opening H_{2B} having an area smaller than that of the first opening H_{2A} is formed on the p type semiconductor layer 5 in the first opening H_{2A}. Next, using this resist mask, the p type contact layer 9 and the p type source layer 10 are sequentially formed in the second opening H_{2B}. Subsequently, the resist mask is removed through a liftoff process.

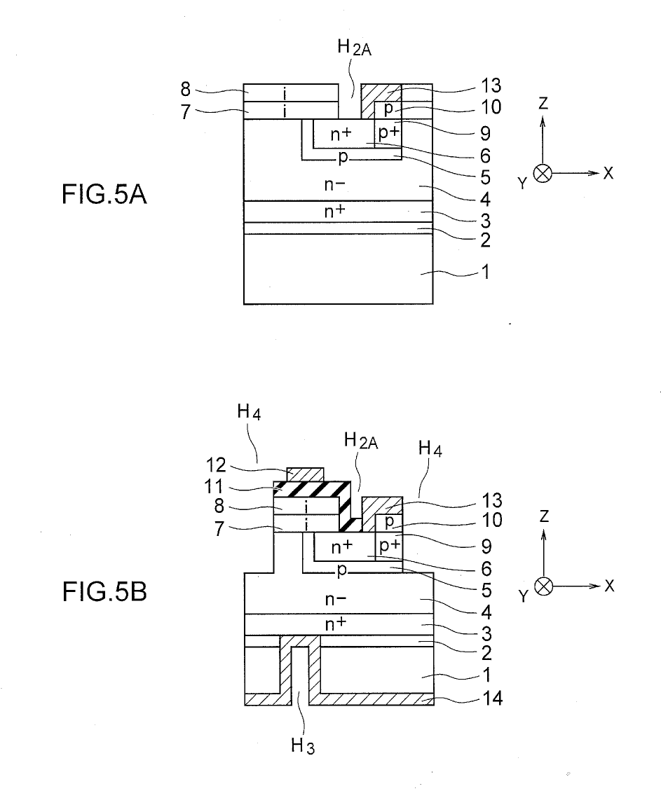

Next, as shown in FIG. 5A, the source electrode 13 is formed on the second n type contact layer 6 and the p type source layer 10 in a state that areas other than a formation planned area of the source electrode 13 are covered with resist masks. An example of the material of the source electrode 13 is an ohmic electrode material, and the source electrode 13 is, for example, a stack film that includes at least any one of an Al (aluminum) layer, a Ti (titanium) layer, a Ni (nickel) layer, and an Au (gold) layer. Subsequently, the resist masks are removed through a liftoff process.

Next, as shown in FIG. 5B, the gate insulator 11 is formed on the electron supply layer 8. The gate insulator 11 may be formed on the electron supply layer 8 and the source electrode 13. Next, the gate electrode 12 is formed on the electron supply layer 8 through the gate insulator 11.

Next, as shown in FIG. 5B, an opening H₃ used to form the drain electrode 14 is formed on the back face of the substrate 1. The opening H₃ is formed so as to penetrate the substrate 1 and the buffer layer 2 to reach the first n type contact layer 3. Next, the drain electrode 14 is formed on the upper portion and the side portions of the opening H₃ and on the lower portions of the substrate 1. An example of the material of the drain electrode 14 is an ohmic electrode material, and the drain electrode 14 is, for example, a stack film that includes at least any one of an Al layer, a Ti layer, a Ni layer, and an Au layer.

Next, as shown in FIG. 5B, by means of lithography and etching, openings H₄ used for the element isolation are formed on the substrate 1. Consequently, the HEMT is formed on the substrate 1.

Subsequently, the interlayer dielectric 15 is formed on the substrate 1. Furthermore, various interlayer dielectrics, interconnect layer, and the like are formed on the substrate 1. In such a manner, the semiconductor device of the first embodiment can be manufactured.

As described above, the electron transport layer 7 of the present embodiment is formed on the drift layer 4, the p type semiconductor layer 5, and the second n type contact layer 6, and the electron supply layer 8 of the present embodiment is formed on the semi-polar face of the electron transport layer 7. Therefore, according to the present embodiment, it is possible to suppress the amount of 2DEG in the interface between the electron transport layer 7 and the electron supply layer 8, which consequently enables reducing the on resistance of a vertical field effect transistor that makes use of a nitride semiconductor material, and enhancing the electron mobility.

### Second Embodiment

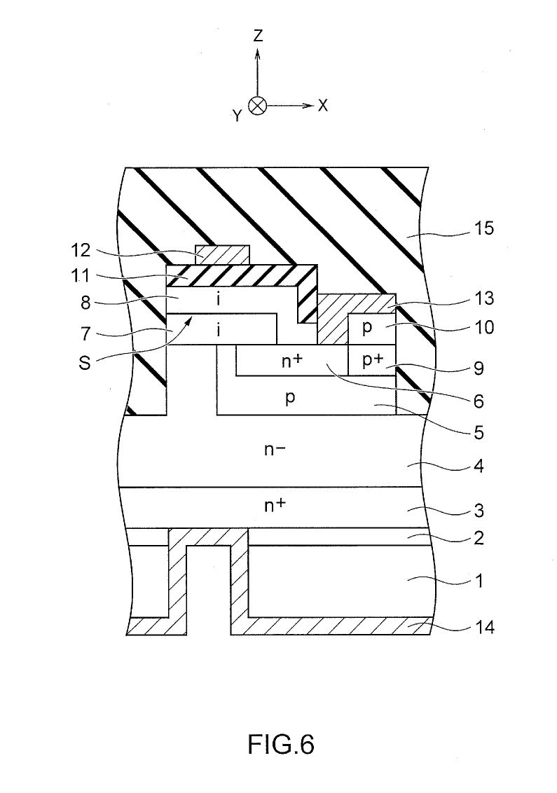

FIG. 6 is a cross sectional view showing a structure of a semiconductor device of a second embodiment.

The electron supply layer 8 in FIG. 6 is in contact with the upper portion and the side portion of the electron transport layer 7, the upper portion of the second n type contact layer 6, and the side portion of the source electrode 13, and is interposed between the second n type contact layer 6 and the source electrode 13. According to the present embodiment, it is possible to reduce the on resistance of a vertical field effect transistor and to enhance the electron mobility more, as compared with the first embodiment.

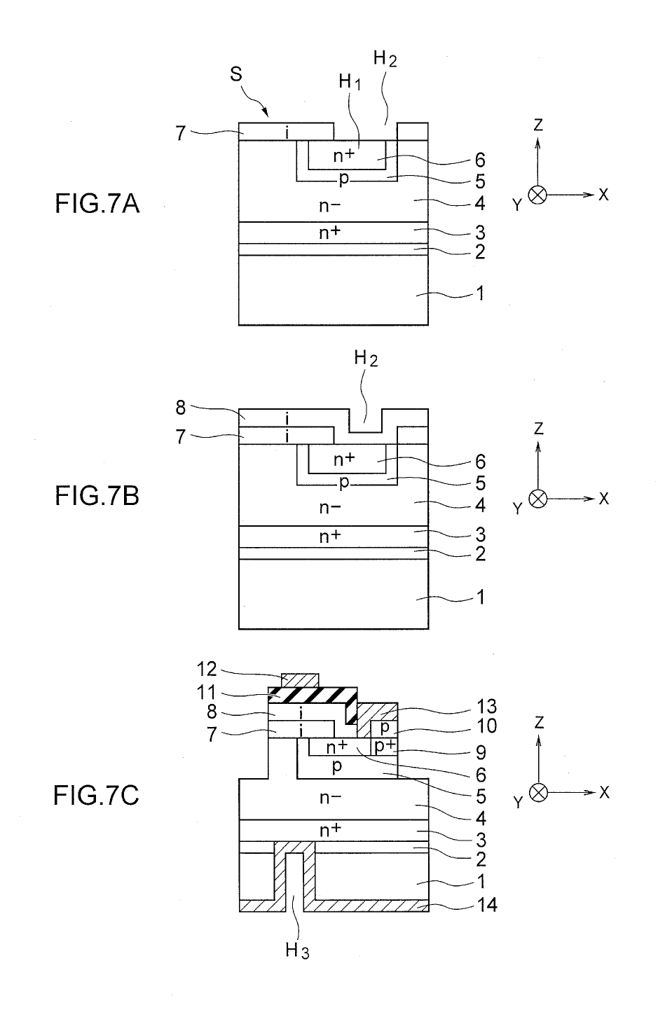

FIGS. 7A to 7C are cross sectional views showing a method of manufacturing the semiconductor device of the second embodiment.

First, the processes of FIGS. 3A to 4A are performed.

Next, as shown in FIG. 7A, part of the electron transport layer 7 is removed by means of lithography and RIE to form an opening H₂.

Next, as shown in FIG. 7B, the electron supply layer 8 is formed on the whole wafer surface. Consequently, the electron supply layer 8 is formed on the upper portion and the side portions of the electron transport layer 7, and on the upper portions of the second n type contact layer 6 and the p type semiconductor layer 5 in the opening H₂.

Next, the processes of FIGS. 4C to 5B are performed. Consequently, as shown in FIG. 7C, the HEMT is formed on the substrate 1. In such a manner, the semiconductor device can be manufactured on the second embodiment.

### Third Embodiment

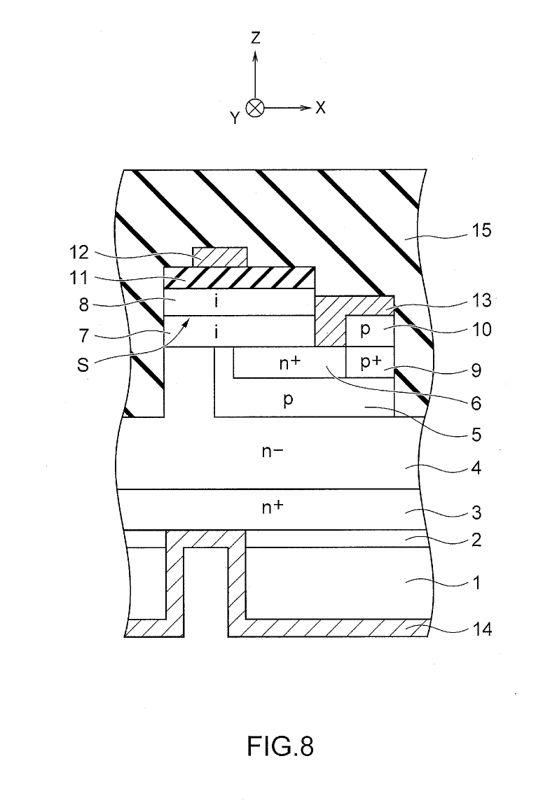

FIG. 8 is a cross sectional view showing a structure of a semiconductor device of a third embodiment.

The electron transport layer 7 and the electron supply layer 8 in FIG. 8 are in contact with the side portion of the source electrode 13. According to the present embodiment, the area of the heterointerface between the electron transport layer 7 and the electron supply layer 8 can be made larger more than those of the first and second embodiments. Therefore, according to the present embodiment, it is possible to enhance the electron mobility of a vertical field effect transistor more than the first and second embodiments.

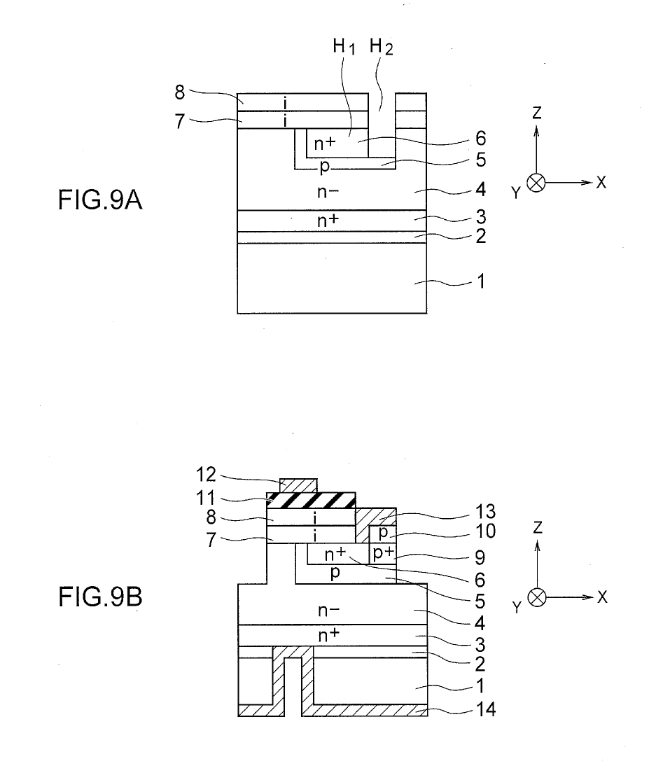

FIGS. 9A and 9B are cross sectional views showing a method of manufacturing the semiconductor device of the third embodiment.

First, the processes of FIGS. 3A to 4B are performed.

Next, as shown in FIG. 9A, by means of lithography and RIE, an opening H₂ that penetrates the electron supply layer 8, the electron transport layer 7, and the second n type contact layer 6 is formed.

Next, the process of FIG. 4C is performed in a state that areas other than the opening H₂ are covered with a resist mask. Next, the processes of FIG. 5A and FIG. 5B are performed. Consequently, as shown in FIG. 9B, the HEMT is formed on the substrate 1. In such a manner, the semiconductor device of the third embodiment can be manufactured.

### Fourth Embodiment

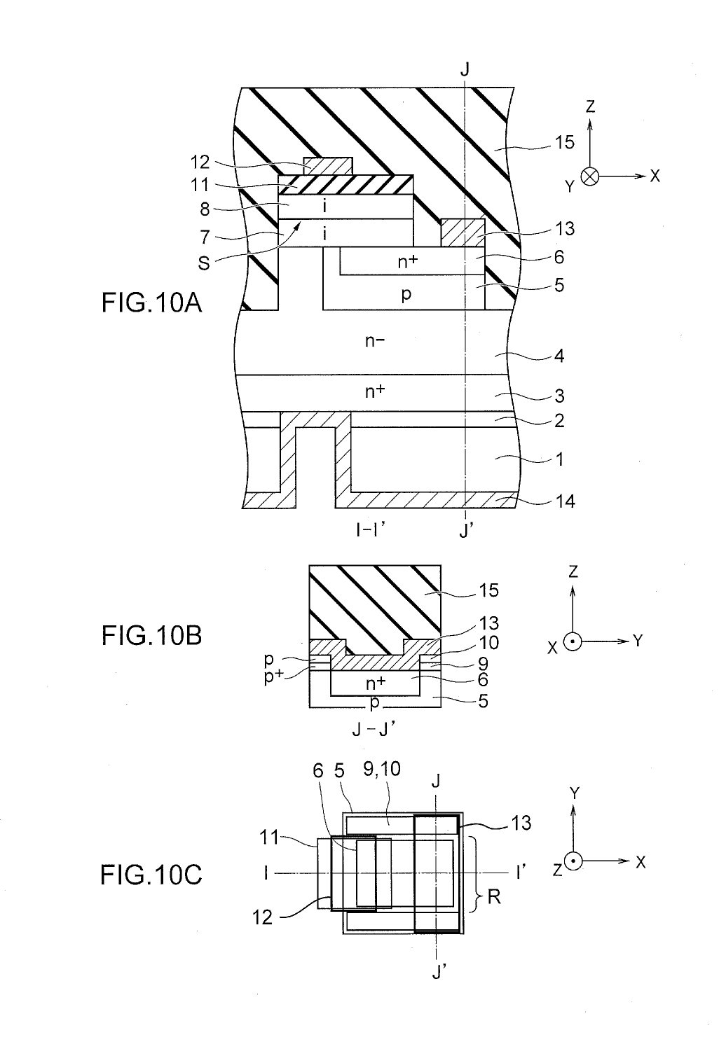

FIGS. 10A to 10C are cross sectional views and a plan view showing the structure of a semiconductor device of a fourth embodiment.

FIG. 10A is the cross sectional view taken along an I-I′ line in the plan view of FIG. 10C. FIG. 10B is a cross sectional view taken along J-J′ lines in the plan view of FIG. 10C and in the cross sectional view of FIG. 10A. Reference character R in FIG. 10C denotes an operating region of the HEMT. In FIG. 10B and FIG. 10C, the illustrations of the substrate 1, the buffer layer 2, the first n type contact layer 3, and the drift layer 4 are omitted.

The semiconductor device of the present embodiment includes, as shown in FIG. 10B and FIG. 10C, two sets of the p type contact layers 9 and the p type source layers 10 that are disposed so as to sandwich the operating region R. The p type contact layer 9 and the p type source layer 10 of one of the sets are disposed in a +Y direction with respect to the source electrode 13, and the p type contact layer 9 and the p type source layer 10 of the other set are disposed in a −Y direction with respect to the source electrode 13. The source electrode 13 is disposed between the former set and the latter set.

The electron transport layer 7 and the electron supply layer 8 of the present embodiment have the same shapes as those of the first embodiment, and may have the same shapes as those of the second and third embodiments. According to the present embodiment, as compared with the first to third embodiments, the width of the HEMT in the X direction can be shortened.

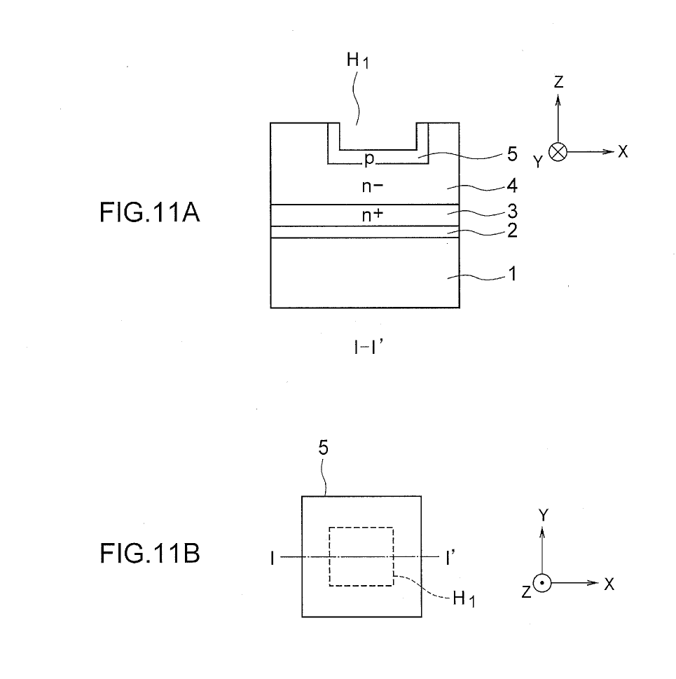

FIGS. 11A to 14C are cross sectional views and plan views showing a method of manufacturing the semiconductor device of the fourth embodiment.

First, as shown in FIG. 11A and FIG. 11B, the buffer layer 2, the first n type contact layer 3, and the drift layer 4 are sequentially formed on the substrate 1. Next, by means of lithography and RIE, an opening H₁ is formed in the drift layer 4. Next, the p type semiconductor layer 5 is formed on the side portions and the lower portion of the opening H₁.

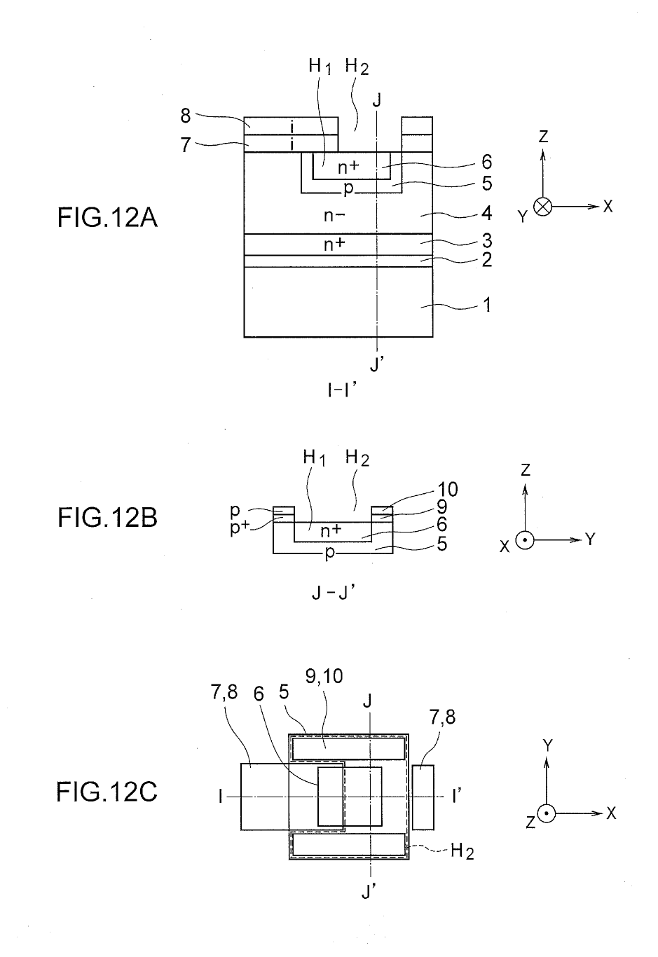

Next, as shown in FIGS. 12A to 12C, the second n type contact layer 6 is formed in the opening H₁ via the p type semiconductor layer 5. Next, the electron transport layer 7 is formed on the drift layer 4, the p type semiconductor layer 5, and the second n type contact layer 6, and the electron supply layer 8 is formed on the upper face S (semi-polar face) of the electron transport layer 7. For the sake of convenience of illustration, the electron transport layer 7 and the electron supply layer 8 in FIG. 12C are shown only in the operating region R of the HEMT. Next, by means of lithography and RIE, an opening H₂ that penetrates the electron supply layer 8 and the electron transport layer 7 is formed. Next, as shown in FIG. 12B and FIG. 12C, the p type contact layers 9 and the p type source layers 10 are sequentially formed on the p type semiconductor layer 5 in the opening H₂ in a state that areas other than formation planned area of the p type contact layers 9 and the p type source layers 10 are covered with resist masks. In such a manner, the two sets of the p type contact layers 9 and the p type source layers 10 sandwiching the operating region R are formed.

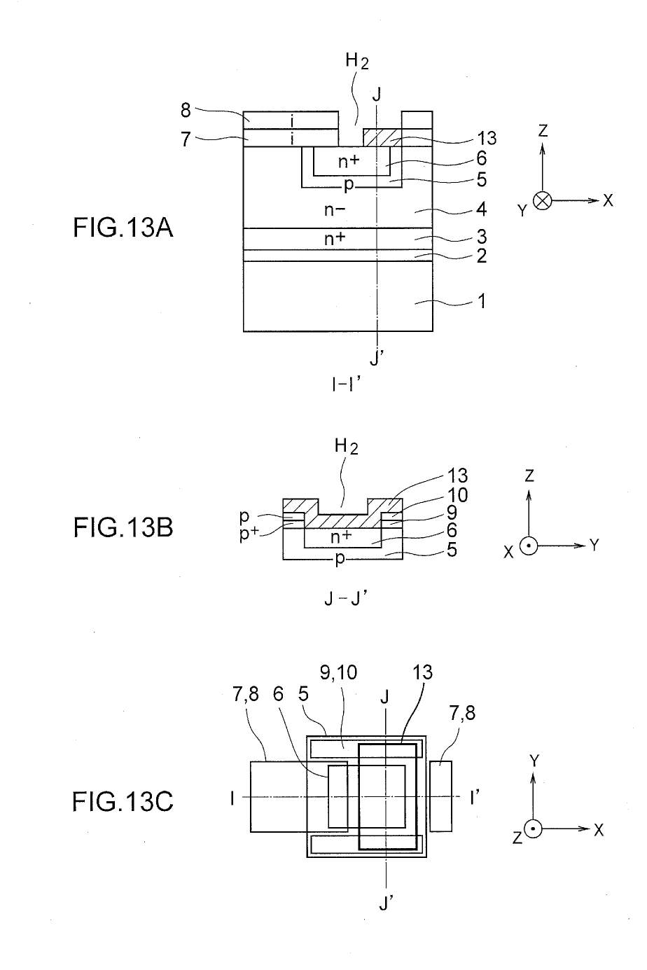

Next, as shown in FIGS. 13A to 13C, the source electrode 13 is formed on the p type semiconductor layer 5, the second n type contact layer 6, and the p type source layer 10 in a state that areas other than the formation planned area of the source electrode 13 are covered with resist masks.

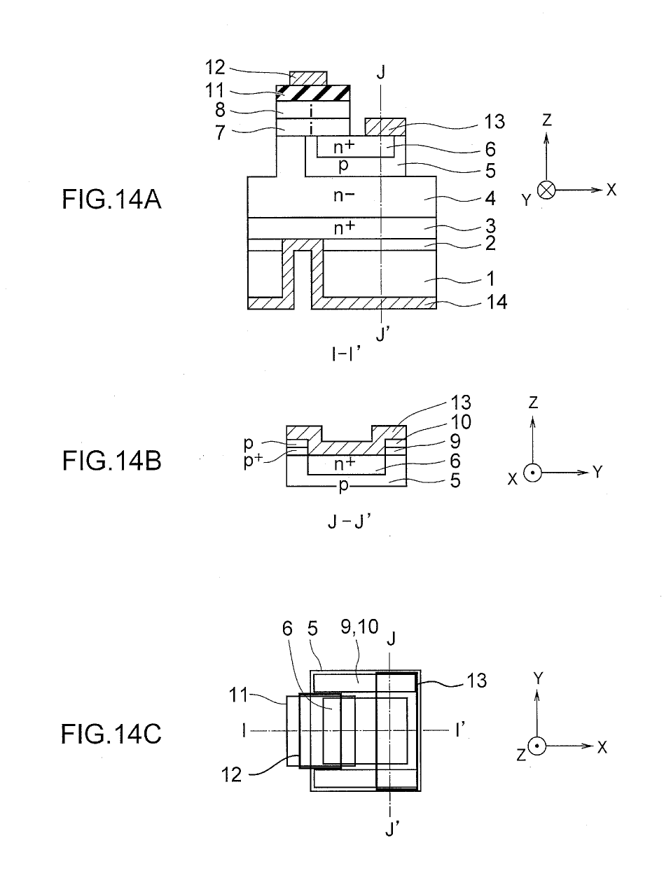

Next, the process of FIG. 5B is performed. Consequently, as shown in FIGS. 14A to 14C, the HEMT is formed on the substrate 1. In such a manner, the semiconductor device of the fourth embodiment can be manufactured.

### Fifth Embodiment

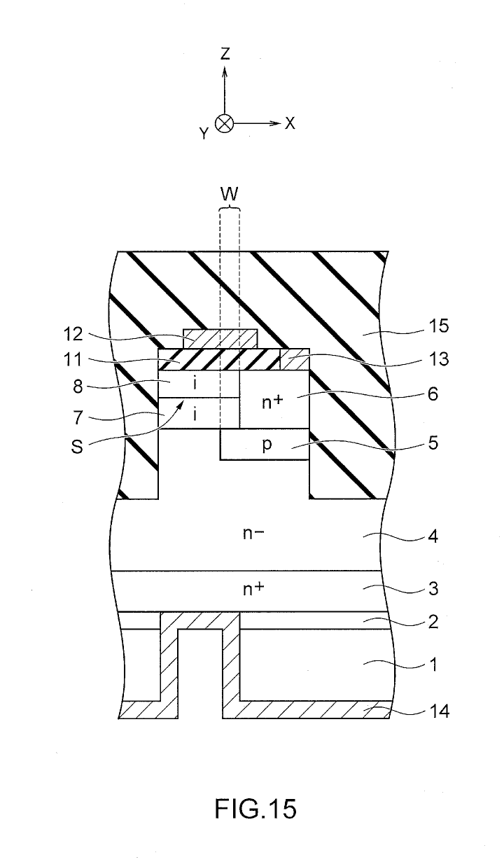

FIG. 15 is a cross sectional view showing a structure of a semiconductor device of a fifth embodiment.

In the present embodiment, the drift layer 4 and the p type semiconductor layer 5 are in contact with the lower portion of the electron transport layer 7, and the second n type contact layer 6 is in contact with the side portions of the electron transport layer 7 and the electron supply layer 8. Reference character W denotes the width of the interface between the p type semiconductor layer 5 and the electron transport layer 7 in the X direction. An example of the width W in the present embodiment is 100 nm or less.

In addition, the semiconductor device of the present embodiment includes, as with the fourth embodiment, two sets of the p type contact layers 9 and the p type source layers 10 (not shown). The p type contact layer 9 and the p type source layer 10 of one of the sets are disposed in the +Y direction with respect to the source electrode 13, and the p type contact layers 9 and the p type source layer 10 of the other set are disposed in the −Y direction with respect to the source electrode 13. The source electrode 13 is disposed between the former set and the latter set.

According to the present embodiment, as compared with the first to third embodiments, the width of the HEMT in the X direction can be shortened.

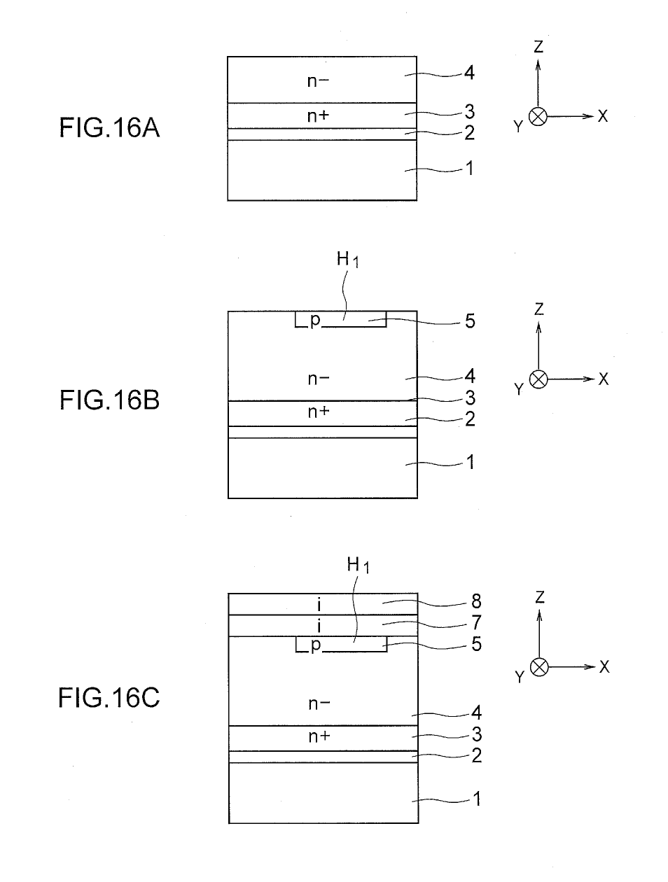

FIGS. 16A to 20C are cross sectional views and plan views showing a method of manufacturing the semiconductor device of the fifth embodiment.

First, as shown in FIG. 16A, the buffer layer 2, the first n type contact layer 3, and the drift layer 4 are sequentially formed on the substrate 1.

Next, as shown in FIG. 16B, by means of lithography and RIE, an opening H₁ is formed in the drift layer 4. Next, the p type semiconductor layer 5 is formed in the opening H₁. The thickness of the p type semiconductor layer 5 is, for example, 100 nm or less.

Next, as shown in FIG. 16C, the electron transport layer 7 is formed on the drift layer 4 and the p type semiconductor layer 5, and the electron supply layer 8 is formed on the upper face S (semi-polar face) of the electron transport layer 7.

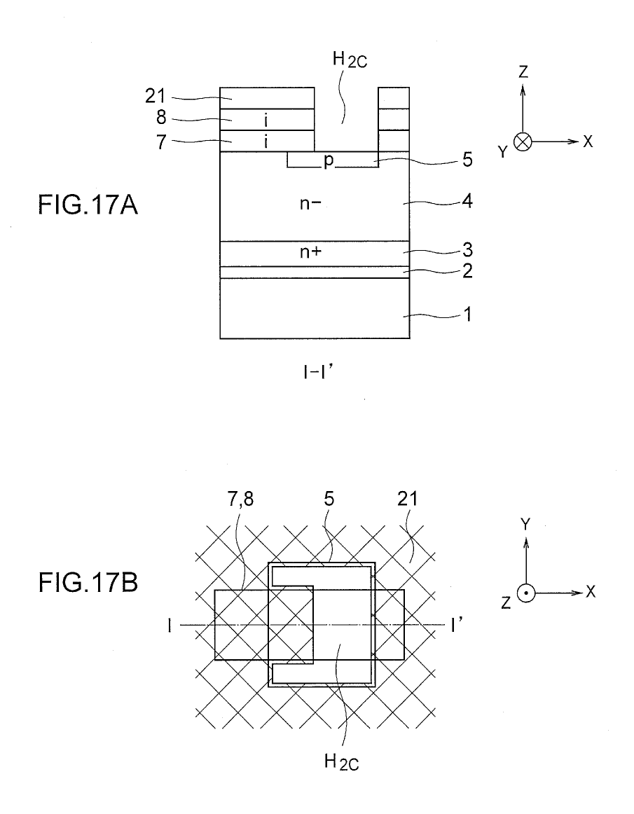

Next, as shown in FIG. 17A and FIG. 17B, by means of RIE using resist masks 21, an opening H_{2C} that penetrates the electron supply layer 8 and the electron transport layer 7 is formed. For the sake of convenience of illustration, the electron transport layer 7 and the electron supply layer 8 in FIG. 17B are shown only in the operating region R of the HEMT. Next, the resist masks 21 are removed.

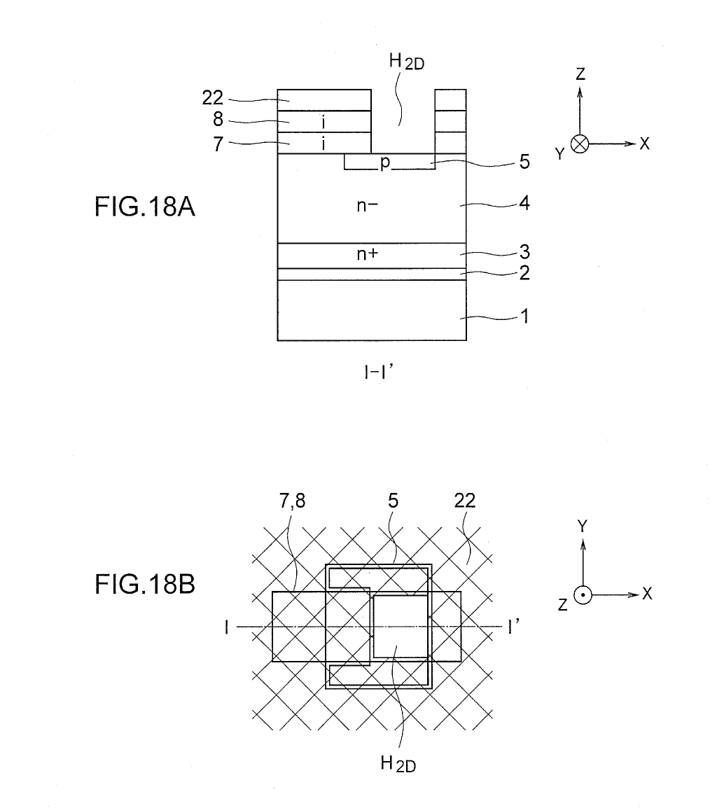

Next, as shown in FIG. 18A and FIG. 18B, a resist mask 22 with which an area other than the formation planned area of the second n type contact layer 6 is covered and which has an opening H_{2D}, is formed.

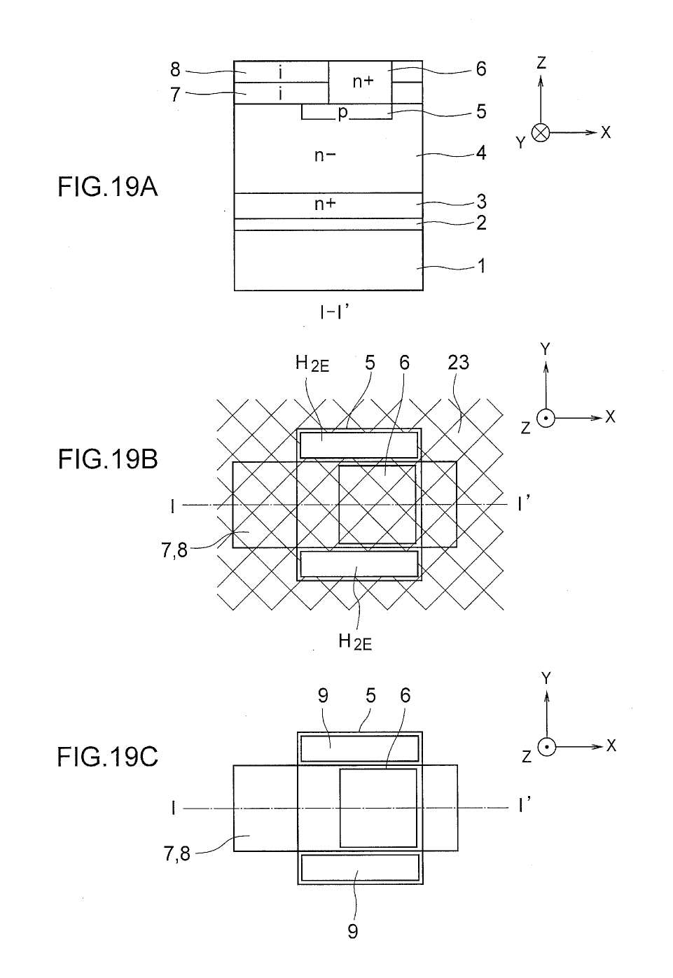

Next, as shown in FIG. 19A, using the resist mask 22, the second n type contact layer 6 is formed on the p type semiconductor layer 5 in the opening H_{2D}. Next, the resist mask 22 is removed.

Next, as shown in FIG. 19B, a resist mask 23 is formed on an area other than the formation planned areas of the p type contact layers 9 and the p type source layers 10, and openings H_{2E} to expose the p type semiconductor layer 5 are formed by means of etching such as RIE.

Next, as shown in FIG. 19C, using the resist mask 23, the p type contact layers 9 and the p type source layers 10 are sequentially formed on the p type semiconductor layer 5 in the openings H_{2E}. Subsequently, the resist mask 23 is removed through a liftoff process.

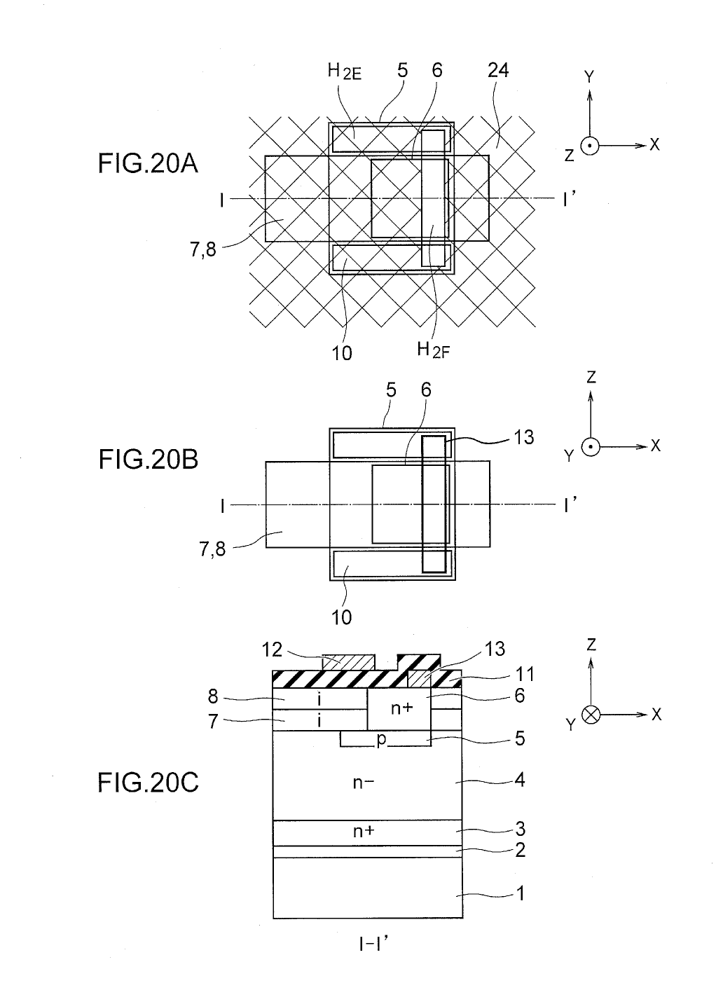

Next, as shown in FIG. 20A, a resist is applied on the whole wafer surface, a resist mask 24 having an opening H_{2F} with which an area other than the formation planned area of the source electrode 13 is covered is formed by means of lithography.

Next, as shown in FIG. 20B, the source electrode 13 is formed in the opening H_{2F}. Subsequently, the resist mask 24 and the ohmic electrode material thereon are removed through a liftoff process.

Next, as shown in FIG. 20C, the gate insulator 11 is formed on the whole wafer surface, and by means of lithography and etching, the gate electrode 12 is formed on the electron supply layer 8 and the second n type contact layer 6 via the gate insulator 11. Subsequently, a resist mask (not shown) and the gate electrode material thereon are removed through a liftoff process.

Next, the process of FIG. 5B is performed. Consequently, as shown in FIG. 15, the HEMT is formed on the substrate 1. In such a manner, the semiconductor device of the fifth embodiment can be manufactured.

The substrate 1 of the first to fifth embodiments may be a GaN substrate instead of a silicon substrate. Using a GaN substrate as the substrate 1 offers an advantage in that there is a small difference of lattice constants between the substrate 1 and a nitride semiconductor layer stacked thereon. Therefore, in this case, the opening H₃ does not need to be formed on the back face of the substrate 1.

While certain embodiments have been described, these embodiments have been presented by way of example only, and are not intended to limit the scope of the inventions. Indeed, the novel devices and methods described herein may be embodied in a variety of other forms; furthermore, various omissions, substitutions and changes in the form of the devices and methods described herein may be made without departing from the spirit of the inventions. The accompanying claims and their equivalents are intended to cover such forms or modifications as would fall within the scope and spirit of the inventions.

1. A semiconductor device comprising:
a first semiconductor layer of a first conductivity type or an intrinsic type;
a second semiconductor layer of a second conductivity type provided on the first semiconductor layer;
a third semiconductor layer of the first conductivity type provided on the second semiconductor layer;
a fourth semiconductor layer in contact with the first, second and third semiconductor layers;
a fifth semiconductor layer provided on a semi-polar face of the fourth semiconductor layer; and
a control electrode provided on the fifth semiconductor layer through an insulating layer.

2. The device of claim 1, wherein the fifth semiconductor layer is in contact with the third and fourth semiconductor layers.

3. The device of claim 1, further comprising:
a first electrode provided on the third semiconductor layer; and
a second electrode provided below the first semiconductor layer.

4. The device of claim 3, wherein the fifth semiconductor layer is provided between the fourth semiconductor layer and the first electrode.

5. The device of claim 3, wherein the fourth and fifth semiconductor layers are in contact with the first electrode.

6. The device of claim 3, further comprising:
a sixth semiconductor layer of the second conductivity type in contact with the second and third semiconductor layers; and
a seventh semiconductor layer of the second conductivity type provided on the sixth semiconductor layer,
wherein the first electrode is provided on the seventh semiconductor layer.

7. The device of claim 3, further comprising:
a first set of sixth and seventh semiconductor layers of the second conductivity type sequentially provided on the second semiconductor layer; and
a second set of sixth and seventh semiconductor layers and of the second conductivity type sequentially provided on the second semiconductor layer,
wherein the first electrode is provided on the seventh semiconductor layers of the first and second sets, and is provided between the first set of sixth and seventh semiconductor layers and the second set of sixth and seventh semiconductor layers.

8. The device of claim 1, wherein the first, second and third semiconductor layers are in contact with a lower portion of the fourth semiconductor layer.

9. The device of claim 1, wherein
the first and second semiconductor layers are in contact with a lower portion of the fourth semiconductor layer, and
the third semiconductor layer is in contact with side portions of the fourth and fifth semiconductor layers.

10. The device of claim 1, wherein the semi-polar face of the fourth semiconductor layer is nonparallel and nonorthogonal to a polar face of the fourth semiconductor layer.

11. A method of manufacturing a semiconductor device, comprising:
forming a first semiconductor layer of a first conductivity type or an intrinsic type;
forming a second semiconductor layer of a second conductivity type on the first semiconductor layer;
forming a third semiconductor layer of the first conductivity type on the second semiconductor layer;
forming a fourth semiconductor layer in contact with the first, second and third semiconductor layers;
forming a fifth semiconductor layer on a semi-polar face of the fourth semiconductor layer; and
forming a control electrode on the fifth semiconductor layer through an insulating layer.

12. The method of claim 11, wherein the fifth semiconductor layer is formed to be in contact with the third and fourth semiconductor layers.

13. The method of claim 11 further comprising:
forming a first electrode on the third semiconductor layer; and
forming a second electrode below the first semiconductor layer.

14. The method of claim 13, wherein the fifth semiconductor layer is formed between the fourth semiconductor layer and the first electrode.

15. The method of claim 13, wherein the first electrode is formed to be in contact with the fourth and fifth semiconductor layers.

16. The method of claim 13 further comprising:
forming a sixth semiconductor layer of the second conductivity type in contact with the second and third semiconductor layers; and
forming a seventh semiconductor layer of the second conductivity type on the sixth semiconductor layer,
wherein the first electrode is formed on the seventh semiconductor layer.

17. The method of claim 13 further comprising:
sequentially forming a first set of sixth and seventh semiconductor layers of the second conductivity type on the second semiconductor layer; and
sequentially forming a second set of sixth and seventh semiconductor layers of the second conductivity type on the second semiconductor layer,
wherein the first electrode is formed on the seventh semiconductor layers of the first and second sets, and is formed between the first set of sixth and seventh semiconductor layers and the second set of sixth and seventh semiconductor layers.

18. The method of claim 11, wherein the fourth semiconductor layer is formed such that a lower portion of the fourth semiconductor layer is in contact with the first, second and third semiconductor layers.

19. The method of claim 11, wherein the third, fourth and fifth semiconductor layers are formed such that a lower portion of the fourth semiconductor layer is in contact with the first and second semiconductor layers, and the third semiconductor layer is in contact with side portions of the fourth and fifth semiconductor layers.

20. The method of claim 11, wherein the second and third semiconductor layers are formed by forming an opening in the first semiconductor layer, forming the second semiconductor layer in the opening, and forming the third semiconductor layer in the opening through the second semiconductor layer.
